(19) United States
(12) Patent Application Publication
(10) Pub. No.: US 2010/0245370 A1
(43) Pub. Date: Sep. 30, 2010

(54) EM SHIELDING FOR DISPLAY DEVICES

(75) Inventors: Kollengode S. Narayanan, Cupertino, CA (US); Ion Bita, San Jose, CA (US); Brian J. Gally, Los Gatos, CA (US); Jeffrey B. Sampsell, Pueblo West, CO (US)

Correspondence Address: KNOBBE, MARTENS, OLSON & BEAR, LLP, 2040 MAIN STREET, FOURTEENTH FLOOR, IRVINE, CA, 92614, US

(73) Assignee: QUALCOMM MEMS Technologies, Inc., San Diego, CA (US)

(21) Appl. No.: 12/730,142

(22) Filed: Mar. 23, 2010

Related U.S. Application Data
(60) Provisional application No. 61/163,396, filed on Mar. 25, 2009.

(51) Int. Cl. G06T 15/00; F21V 9/06; F21V 9/04; H05K 13/00

(52) U.S. Cl. 345/522; 359/361; 359/359; 29/592.1

(57) ABSTRACT

A shielding material that can be arranged with respect to display elements to reduce potential damage or degraded performance caused by incident EM, such as UV and/or IR. The shielding material can be configured to be substantially transparent in visible light wavelengths. The shielding material can include inorganic materials, such as oxides including zinc oxide and titanium dioxide. Display elements can include a shielding material and an outer coating to reduce undesirable optical characteristics of an air/shielding material interface. The shielding material can be electrically conductive and function as a conductive layer in a microelectromechanical system (MEMS) device. In some embodiments, the shielding material can be disposed forward (closer to the viewer) of the electrodes of the display elements to prevent the high energy UV light from building up electrical charge in the electrodes. In some embodiments, the shielding material can also block certain wavelengths of light in the visible spectrum to darken the dark state of the display elements to improve the contrast ratio of the display.

### CROSS-REFERENCE TO RELATED APPLICATIONS

This application claims the benefit of U.S. Provisional Application No. 61/163,396, filed on Mar. 25, 2009, entitled EM SHIELDING FOR DISPLAY DEVICES, the entirety of which is incorporated by reference herein.

### BACKGROUND OF THE INVENTION

1. Field of the Invention

The invention relates to the field of display devices and to providing shielding materials/layers to protect display devices from incident electromagnetic (EM) energy, such as UV and/or IR light.

2. Description of the Related Art

Microelectromechanical systems (MEMS) can include micro mechanical elements, actuators, and electronics. Micromechanical elements may be created using deposition, etching, and/or other micromachining processes that etch away parts of substrates and/or deposited material layers or that add layers to form electrical and electromechanical devices. One type of MEMS device is called an interferometric modulator. As used herein, the term interferometric modulator or interferometric light modulator refers to a device that selectively absorbs and/or reflects light using the principles of optical interference. In certain embodiments, an interferometric modulator may comprise a pair of conductive plates, one or both of which may be transparent and/or reflective in whole or part and capable of relative motion upon application of an appropriate electrical signal.

In a particular embodiment, one plate may comprise a stationary layer deposited on a substrate and the other plate may comprise a metallic membrane separated from the stationary layer by an air gap. As described herein in more detail, the position of one plate in relation to another can change the optical interference of light incident on the interferometric modulator. Such devices have a wide range of applications, and it would be beneficial in the art to utilize and/or modify the characteristics of these types of devices so that their features can be exploited in improving existing products and creating new products that have not yet been developed.

### SUMMARY

Embodiments can include shielding material(s) that can be arranged with respect to one or more display elements to reduce potential damage from incident EM, such as UV and/or IR light. The shielding material can be configured to be substantially transparent in visible light wavelengths. The shielding material can include inorganic materials, such as oxides including zinc oxide and titanium dioxide. Display elements can include a shielding material and an outer coating to reduce undesirable optical characteristics of an air/shielding material interface. In some embodiments, the shielding material can be electrically conductive and function as a conductive layer in a microelectromechanical system (MEMS) device. In some embodiments, the shielding material can be nonconductive. In some embodiments, the shielding material can include substantially no organic materials, and/or can include substantially only organic materials.

By way of example, and not limitation, a display device is disclosed. The display device can include a substrate and a plurality of display elements arranged on a first side of the substrate. The display can also include a nonconductive UV shielding layer. In some embodiments, the UV shielding layer can include substantially no organic material. The UV shielding layer can be disposed forward of the plurality of display elements such that visible light passes through the UV shielding layer to the plurality of display elements and such that the UV shielding layer blocks UV light that is incident on the UV shielding layer from reaching the plurality of display elements.

In some embodiments, the UV shielding layer blocks 95% or more of UV light below 350 nm in wavelength that is incident on the UV shielding layer from reaching the plurality of display elements. The UV shielding layer can include an oxide. The UV shielding layer can include zinc oxide. The UV shielding layer can include substantially only inorganic material.

The plurality of display elements can include MEMS devices. The plurality of display elements can include interferometric modulators.

The UV shielding layer can be disposed between the substrate and the plurality of display elements. The UV shielding layer can be formed on the first side of the substrate. The substrate can be disposed between the UV shielding layer and the plurality of display elements. The UV shielding layer can be formed on a second side of the substrate that is opposite the first side. The display device can further include an outer coating overlying the UV shielding layer, and the outer coating can include at least one of an anti-reflective coating, an anti-scratch coating, and a filter coating.

The UV shielding layer can include a plurality of UV shielding particles dispersed in a matrix material. The matrix material can be glass. The UV shielding layer can include molecular precursors for the UV shielding particles. The UV shielding layer can include a heterogeneous layer of inorganic materials. The UV shielding particles can be configured to reflect IR light. The UV shielding particles can be transparent conductor particles. The UV shielding layer can further include inorganic blue absorbing particles configured to absorb visible light near the UV spectrum dispersed in the matrix material. The blue absorbing particles can include semiconductor nanocrystals.

The UV shielding layer can include a substantially homogenous layer of inorganic material. The UV shielding layer can block 99% or more of UV light below 350 nm in wavelength that is incident on the UV shielding layer. In some embodiments, the UV shielding layer absorbs no more than 1% of visible light that is incident on the UV shielding layer. At least one of the plurality of display elements can include an optical stack, and the optical stack can include the UV shielding layer.

The display device can further include a processor that is configured to communicate with said display device, and the processor can be configured to process image data. The display device can also include a memory device that is configured to communicate with said processor. The display device can further include a driver circuit configured to send at least one signal from the processor to said display device. The display device can further include a controller configured to send at least a portion of said image data to said driver circuit. The display device can further include an image source module configured to send said image data to said processor. The image source module can include at least one of a receiver, transceiver, and transmitter. The display device can further include an input device configured to receive input data and to communicate said input data to said processor.

The display device can further include a light assembly arranged to direct light towards the plurality of display elements. The light assembly can include a light guide.

In some embodiments, the UV shielding layer can include titanium dioxide particles suspended in a matrix, and the matrix can be selected to have an index of refraction such that the UV shielding layer transmits 95% or more of visible light.

In some embodiments, at least one of the plurality of display elements can include one or more electrodes for facilitating the actuation of the at least one display element, and the UV shielding layer can be disposed forward of the one or more electrodes such that the UV shielding layer blocks UV light that is incident on the UV shielding layer from reaching the one or more electrodes. In some embodiments, the UV shielding layer blocks 95% or more of UV light below 350 nm in wavelength that is incident on the UV shielding layer from reaching the one or more electrodes.

A method of manufacturing a display device is also disclosed. The method includes providing a substrate, arranging a plurality of display elements on a first side of the substrate, and disposing a nonconductive UV shielding layer that includes substantially no organic material forward of the plurality of display elements such that visible light passes through the UV shielding layer to the plurality of display elements and such that UV light that is incident on the UV shielding layer is blocked from reaching the plurality of display elements. In some embodiments, the UV shielding layer blocks 95% or more of UV light below 350 nm in wavelength that is incident on the UV shielding layer from reaching the plurality of display elements.

Another embodiment of a display device is disclosed. The display device includes means for supporting, means for displaying an image arranged on a first side of the supporting means, and means for UV shielding disposed forward of the displaying means. In some embodiments, visible light can pass through the UV shielding means to the displaying means, and the UV shielding means can block UV light that is incident on the UV shielding means from reaching the displaying means. In some embodiments, the UV shielding means can include substantially only inorganic material. In some embodiments, the UV shielding means can block 95% or more of UV light that is incident on the UV shielding means from reaching the displaying means.

The supporting means can include a transparent substrate. The displaying means can include a plurality of display elements. The UV shielding means can include a UV shielding layer.

Another display device is disclosed. The display device can include at least one display element having a dark state and a light state, and the at least one display element can emit visible light near the UV spectrum when in the dark state. The display device can also include an optical shielding layer disposed forward of the at least one display element such that visible light passes through the optical shielding layer to the at least one display element. The optical shielding layer can block visible light near the UV spectrum so as to darken the dark state of the at least one display element.

The optical shielding layer can absorb an average of at least about 50% of visible light below 400 nm in wavelength that is incident on the optical shielding layer. In some embodiments, the optical shielding layer can block UV light that is incident on the optical shielding layer from reaching the at least one display element. In some embodiments, the optical shielding layer can include substantially only inorganic material. The optical shielding layer can include zinc oxide. The optical shielding layer can include multiple layers, wherein a first layer is configured to block the UV light and a second layer is configured to block the visible light near the UV spectrum. The optical shielding layer can include a single layer configured to block both the UV light and the visible light near the UV spectrum.

Another display device is disclosed. The display device can include a substrate and a plurality of display elements arranged on a first side of the substrate. The display can also include an IR shielding layer. The IR shielding layer can include substantially no organic material. The IR shielding layer can be disposed forward of the plurality of display elements such that visible light passes through the IR shielding layer to the plurality of display elements and such that the IR shielding layer blocks IR light that is incident on the IR shielding layer from reaching the plurality of display elements.

In some embodiments, the IR shielding layer can block at least about 50% of IR light above about 3 microns in wavelength that is incident on the IR shielding layer from reaching the plurality of display elements. The IR shielding layer can include a plurality of IR shielding particles dispersed in a matrix material. The IR shielding particles can be transparent conductor particles. The transparent conductor particles can be zinc oxide doped with aluminum. In some embodiments, the IR shielding layer can be nonconductive.

### BRIEF DESCRIPTION OF THE DRAWINGS

FIG. 1 is an isometric view depicting a portion of one embodiment of an interferometric modulator display in which a movable reflective layer of a first interferometric modulator is in a relaxed position and a movable reflective layer of a second interferometric modulator is in an actuated position.

FIG. 2 is a system block diagram illustrating one embodiment of an electronic device incorporating a 3×3 interferometric modulator display.

FIG. 3 is a diagram of movable mirror position versus applied voltage for one exemplary embodiment of an interferometric modulator of FIG. 1.

FIG. 4 is an illustration of a set of row and column voltages that may be used to drive an interferometric modulator display.

FIGS. 5A and 5B illustrate one exemplary timing diagram for row and column signals that may be used to write a frame of display data to the 3×3 interferometric modulator display of FIG. 2.

FIGS. 6A and 6B are system block diagrams illustrating an embodiment of a visual display device comprising a plurality of interferometric modulators.

FIG. 7A is a cross section of the device of FIG. 1.

FIG. 7B is a cross section of an alternative embodiment of an interferometric modulator.

FIG. 7C is a cross section of another alternative embodiment of an interferometric modulator.

FIG. 7D is a cross section of yet another alternative embodiment of an interferometric modulator.

FIG. 7E is a cross section of an additional alternative embodiment of an interferometric modulator.

FIG. 8 is a cross section of an embodiment of a display element including an EM shielding layer with an outer coating such as an anti-reflective (AR) coating.

FIG. 9 is a cross section of a further embodiment of a display element including an EM shielding layer between a substrate and an optical stack.

FIG. 10 is a cross section of another embodiment of a display element including an EM shielding layer within an optical stack.

FIG. 11 is a cross section of an additional embodiment of a display element including an EM shielding layer and a lighting assembly.

### DETAILED DESCRIPTION OF THE PREFERRED EMBODIMENTS

The following detailed description is directed to certain specific embodiments. However, the teachings herein can be applied in a multitude of different ways. In this description, reference is made to the drawings wherein like parts are designated with like numerals throughout. The embodiments may be implemented in any device that is configured to display an image, whether in motion (e.g., video) or stationary (e.g., still image), and whether textual or pictorial. More particularly, it is contemplated that the embodiments may be implemented in or associated with a variety of electronic devices such as, but not limited to, mobile telephones, wireless devices, personal data assistants (PDAs), hand-held or portable computers, GPS receivers/navigators, cameras, MP3 players, camcorders, game consoles, wrist watches, clocks, calculators, television monitors, flat panel displays, computer monitors, auto displays (e.g., odometer display, etc.), cockpit controls and/or displays, display of camera views (e.g., display of a rear view camera in a vehicle), electronic photographs, electronic billboards or signs, projectors, architectural structures, packaging, and aesthetic structures (e.g., display of images on a piece of jewelry). MEMS devices of similar structure to those described herein can also be used in non-display applications such as in electronic switching devices.

Various embodiments described herein are based at least in part on an understanding that there exists an unsatisfied need for structures to provide protection against potentially damaging incident EM radiation, which can include UV, in a relatively easy to implement and inexpensive manner. Certain embodiments, therefore, provide UV shielding materials/structures that are compatible with existing fabrication processes and are relatively inexpensive to include. Embodiments can include the ability of shielding against multiple spectra of incident EM, for example one or both of UV and IR spectra. While certain embodiments will be illustrated and explained in detail below with respect to interferometric modulator display elements, it will be understood that this is for illustrative purposes and ease of understanding implementation and advantages of the described embodiments. One of ordinary skill can apply the teachings contained herein to other display technologies without detracting from the scope of the invention.

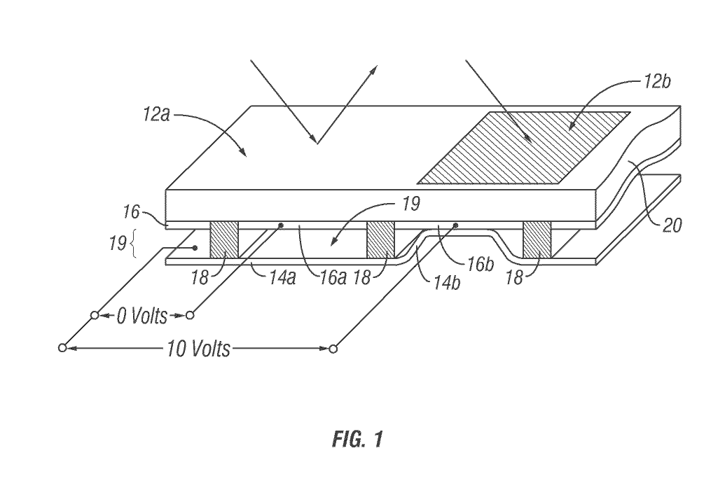

One interferometric modulator display embodiment comprising an interferometric MEMS display element is illustrated in FIG. 1. In these devices, the pixels are in either a bright or dark state. In the bright (“relaxed” or “open”) state, the display element reflects a large portion of incident visible light to a user. When in the dark (“actuated” or “closed”) state, the display element reflects little incident visible light to the user. Depending on the embodiment, the light reflectance properties of the “on” and “off” states may be reversed. MEMS pixels can be configured to reflect predominantly at selected colors, allowing for a color display in addition to black and white. In some embodiments, in the dark state, the display element can reflect more visible light near one or both ends of the visible spectrum than at other portions of the visible spectrum. For example, the display element can reflect more visible light near the UV spectrum than at other portions of the visible spectrum. This reflected far-blue light can cause the dark state of the display element to have a deep blue color which can be close enough to true black to serve as a dark state for a pixel. However, the reflected far-blue light can reduce the contrast ratio between the dark and light states for the display element.

FIG. 1 is an isometric view depicting two adjacent pixels in a series of pixels of a visual display, wherein each pixel comprises a MEMS interferometric modulator. In some embodiments, an interferometric modulator display comprises a row/column array of these interferometric modulators. Each interferometric modulator includes a pair of reflective layers positioned at a variable and controllable distance from each other to form a resonant optical gap with at least one variable dimension. In some embodiments, one of the reflective layers may be moved between two positions. In the first position, referred to herein as the relaxed position, the movable reflective layer is positioned at a relatively large distance from a fixed partially reflective layer. In the second position, referred to herein as the actuated position, the movable reflective layer is positioned more closely adjacent to the partially reflective layer. Incident light that reflects from the two layers interferes constructively or destructively depending on the position of the movable reflective layer, producing either an overall reflective or non-reflective state for each pixel.

The depicted portion of the pixel array in FIG. 1 includes two adjacent interferometric modulators 12a and 12b. In the interferometric modulator 12a on the left, a movable reflective layer 14a is illustrated in a relaxed position at a predetermined distance from an optical stack 16a, which includes a partially reflective layer. In the interferometric modulator 12b on the right, the movable reflective layer 14b is illustrated in an actuated position adjacent to the optical stack 16b.

The optical stacks 16a and 16b (collectively referred to as optical stack 16), as referenced herein, typically comprise several fused layers, which can include an electrode layer, such as indium tin oxide (ITO), a partially reflective layer, such as chromium, and a transparent dielectric. The optical stack 16 is thus electrically conductive, partially transparent and partially reflective, and may be fabricated, for example, by depositing one or more of the above layers onto a transparent substrate 20. The partially reflective layer can be formed from a variety of materials that are partially reflective such as various metals, semiconductors, and dielectrics. The partially reflective layer can be formed of one or more layers of materials, and each of the layers can be formed of a single material or a combination of materials.

In some embodiments, the layers of the optical stack 16 are patterned into parallel strips, and may form row electrodes in a display device as described further below. The movable reflective layers 14a, 14b may be formed as a series of parallel strips of a deposited metal layer or layers (orthogonal to the row electrodes of 16a, 16b) to form columns deposited on top of posts 18 and an intervening sacrificial material deposited between the posts 18. When the sacrificial material is etched away, the movable reflective layers 14a, 14b are separated from the optical stacks 16a, 16b by a defined gap 19. A highly conductive and reflective material such as aluminum may be used for the reflective layers 14, and these strips may form column electrodes in a display device. Note that FIG. 1 may not be to scale. In some embodiments, the spacing between posts 18 may be on the order of 10-100 um, while the gap 19 may be on the order of <1000 Angstroms.

With no applied voltage, the gap 19 remains between the movable reflective layer 14a and optical stack 16a, with the movable reflective layer 14a in a mechanically relaxed state, as illustrated by the pixel 12a in FIG. 1. However, when a potential (voltage) difference is applied to a selected row and column, the capacitor formed at the intersection of the row and column electrodes at the corresponding pixel becomes charged, and electrostatic forces pull the electrodes together. If the voltage is high enough, the movable reflective layer 14 is deformed and is forced against the optical stack 16. A dielectric layer (not illustrated in this Figure) within the optical stack 16 may prevent shorting and control the separation distance between layers 14 and 16, as illustrated by actuated pixel 12b on the right in FIG. 1. The behavior is the same regardless of the polarity of the applied potential difference.

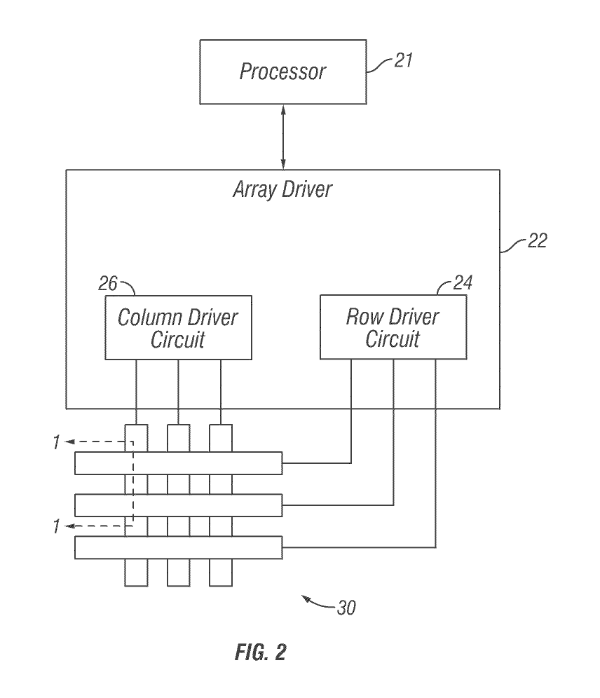

FIGS. 2 through 5 illustrate one exemplary process and system for using an array of interferometric modulators in a display application.

FIG. 2 is a system block diagram illustrating one embodiment of an electronic device that may incorporate interferometric modulators. The electronic device includes a processor 21 which may be any general purpose single- or multi-chip microprocessor such as an ARM®, Pentium®, 8051, MIPS®, Power PC®, or ALPHA®, or any special purpose microprocessor such as a digital signal processor, microcontroller, or a programmable gate array. As is conventional in the art, the processor 21 may be configured to execute one or more software modules. In addition to executing an operating system, the processor may be configured to execute one or more software applications, including a web browser, a telephone application, an email program, or any other software application.

In one embodiment, the processor 21 is also configured to communicate with an array driver 22. In one embodiment, the array driver 22 includes a row driver circuit 24 and a column driver circuit 26 that provide signals to a display array or panel 30. The cross section of the array illustrated in FIG. 1 is shown by the lines 1-1 in FIG. 2. Note that although FIG. 2 illustrates a 3×3 array of interferometric modulators for the sake of clarity, the display array 30 may contain a very large number of interferometric modulators, and may have a different number of interferometric modulators in rows than in columns (e.g., 300 pixels per row by 190 pixels per column).

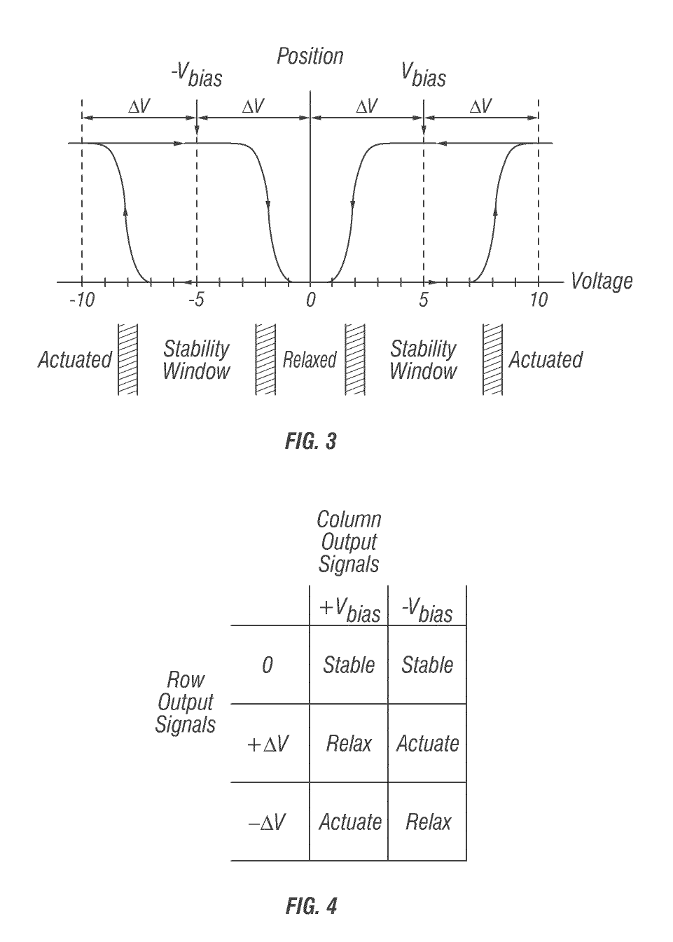

FIG. 3 is a diagram of movable mirror position versus applied voltage for one exemplary embodiment of an interferometric modulator of FIG. 1. For MEMS interferometric modulators, the row/column actuation protocol may take advantage of a hysteresis property of these devices as illustrated in FIG. 3. An interferometric modulator may require, for example, a 10 volt potential difference to cause a movable layer to deform from the relaxed state to the actuated state. However, when the voltage is reduced from that value, the movable layer maintains its state as the voltage drops back below 10 volts. In the exemplary embodiment of FIG. 3, the movable layer does not relax completely until the voltage drops below 2 volts. There is thus a range of voltage, about 3 to 7 V in the example illustrated in FIG. 3, where there exists a window of applied voltage within which the device is stable in either the relaxed or actuated state. This is referred to herein as the “hysteresis window” or “stability window.” For a display array having the hysteresis characteristics of FIG. 3, the row/column actuation protocol can be designed such that during row strobing, pixels in the strobed row that are to be actuated are exposed to a voltage difference of about 10 volts, and pixels that are to be relaxed are exposed to a voltage difference of close to zero volts. After the strobe, the pixels are exposed to a steady state or bias voltage difference of about 5 volts such that they remain in whatever state the row strobe put them in. After being written, each pixel sees a potential difference within the “stability window” of 3-7 volts in this example. This feature makes the pixel design illustrated in FIG. 1 stable under the same applied voltage conditions in either an actuated or relaxed pre-existing state. Since each pixel of the interferometric modulator, whether in the actuated or relaxed state, is essentially a capacitor formed by the fixed and moving reflective layers, this stable state can be held at a voltage within the hysteresis window with almost no power dissipation. Essentially no current flows into the pixel if the applied potential is fixed.

As described further below, in typical applications, a frame of an image may be created by sending a set of data signals (each having a certain voltage level) across the set of column electrodes in accordance with the desired set of actuated pixels in the first row. A row pulse is then applied to a first row electrode, actuating the pixels corresponding to the set of data signals. The set of data signals is then changed to correspond to the desired set of actuated pixels in a second row. A pulse is then applied to the second row electrode, actuating the appropriate pixels in the second row in accordance with the data signals. The first row of pixels are unaffected by the second row pulse, and remain in the state they were set to during the first row pulse. This may be repeated for the entire series of rows in a sequential fashion to produce the frame. Generally, the frames are refreshed and/or updated with new image data by continually repeating this process at some desired number of frames per second. A wide variety of protocols for driving row and column electrodes of pixel arrays to produce image frames may be used.

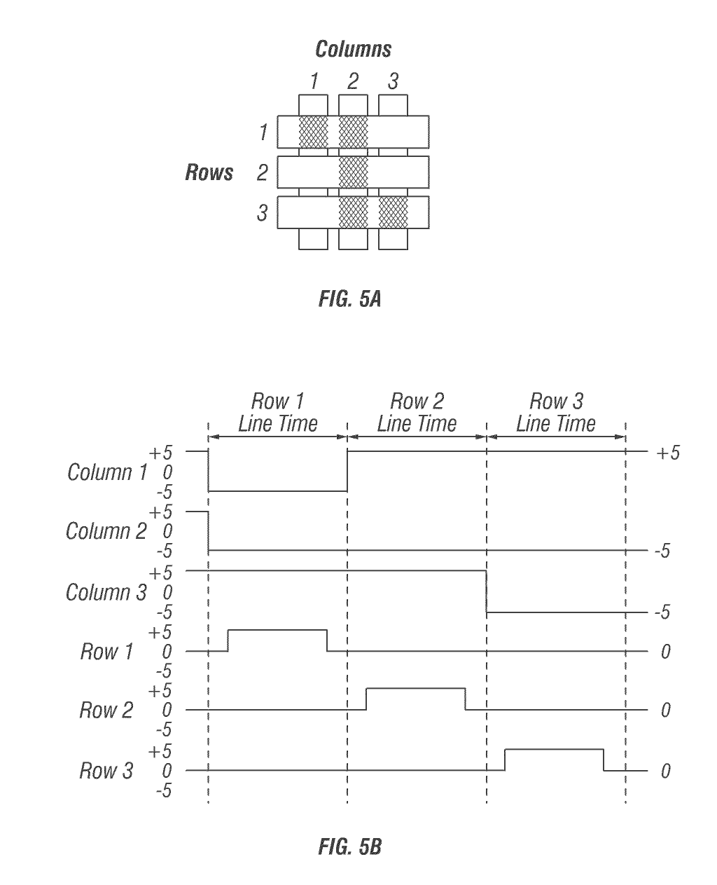

FIGS. 4 and 5 illustrate one possible actuation protocol for creating a display frame on the 3×3 array of FIG. 2. FIG. 4 illustrates a possible set of column and row voltage levels that may be used for pixels exhibiting the hysteresis curves of FIG. 3. In the FIG. 4 embodiment, actuating a pixel involves setting the appropriate column to −V_{bias}, and the appropriate row to +ΔV, which may correspond to −5 volts and +5 volts respectively Relaxing the pixel is accomplished by setting the appropriate column to +V_{bias}, and the appropriate row to the same +ΔV, producing a zero volt potential difference across the pixel. In those rows where the row voltage is held at zero volts, the pixels are stable in whatever state they were originally in, regardless of whether the column is at +V_{bias}, or −V_{bias}. As is also illustrated in FIG. 4, voltages of opposite polarity than those described above can be used, e.g., actuating a pixel can involve setting the appropriate column to +V_{bias}, and the appropriate row to −ΔV. In this embodiment, releasing the pixel is accomplished by setting the appropriate column to −V_{bias}, and the appropriate row to the same −ΔV, producing a zero volt potential difference across the pixel.

FIG. 5B is a timing diagram showing a series of row and column signals applied to the 3×3 array of FIG. 2 which will result in the display arrangement illustrated in FIG. 5A, where actuated pixels are non-reflective. Prior to writing the frame illustrated in FIG. 5A, the pixels can be in any state, and in this example, all the rows are initially at 0 volts, and all the columns are at +5 volts. With these applied voltages, all pixels are stable in their existing actuated or relaxed states.

In the FIG. 5A frame, pixels (1,1), (1,2), (2,2), (3,2) and (3,3) are actuated. To accomplish this, during a “line time” for row 1, columns 1 and 2 are set to −5 volts, and column 3 is set to +5 volts. This does not change the state of any pixels, because all the pixels remain in the 3-7 volt stability window. Row 1 is then strobed with a pulse that goes from 0, up to 5 volts, and back to zero. This actuates the (1,1) and (1,2) pixels and relaxes the (1,3) pixel. No other pixels in the array are affected. To set row 2 as desired, column 2 is set to −5 volts, and columns 1 and 3 are set to +5 volts. The same strobe applied to row 2 will then actuate pixel (2,2) and relax pixels (2,1) and (2,3). Again, no other pixels of the array are affected. Row 3 is similarly set by setting columns 2 and 3 to −5 volts, and column 1 to +5 volts. The row 3 strobe sets the row 3 pixels as shown in FIG. 5A. After writing the frame, the row potentials are zero, and the column potentials can remain at either +5 or −5 volts, and the display is then stable in the arrangement of FIG. 5A. The same procedure can be employed for arrays of dozens or hundreds of rows and columns. The timing, sequence, and levels of voltages used to perform row and column actuation can be varied widely within the general principles outlined above, and the above example is exemplary only, and any actuation voltage method can be used with the systems and methods described herein.

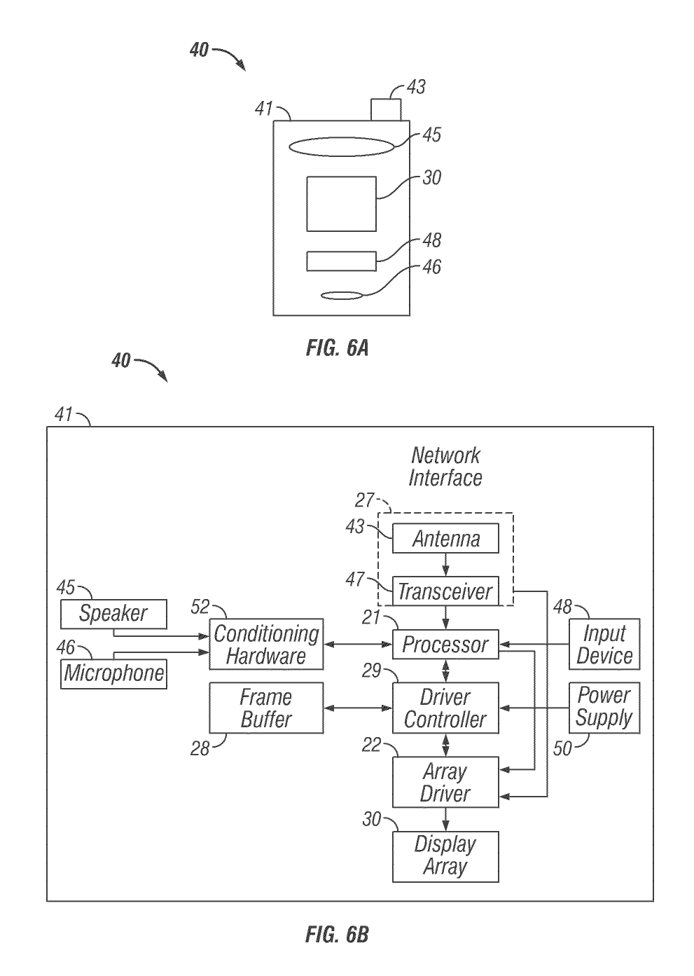

FIGS. 6A and 6B are system block diagrams illustrating an embodiment of a display device 40. The display device 40 can be, for example, a cellular or mobile telephone. However, the same components of display device 40 or slight variations thereof are also illustrative of various types of display devices such as televisions and portable media players.

The display device 40 includes a housing 41, a display 30, an antenna 43, a speaker 45, an input device 48, and a microphone 46. The housing 41 is generally formed from any of a variety of manufacturing processes, including injection molding, and vacuum forming. In addition, the housing 41 may be made from any of a variety of materials, including but not limited to plastic, metal, glass, rubber, and ceramic, or a combination thereof. In one embodiment the housing 41 includes removable portions (not shown) that may be interchanged with other removable portions of different color, or containing different logos, pictures, or symbols.

The display 30 of exemplary display device 40 may be any of a variety of displays, including a bi-stable display, as described herein. In other embodiments, the display 30 includes a flat-panel display, such as plasma, EL, OLED, STN LCD, or TFT LCD as described above, or a non-flat-panel display, such as a CRT or other tube device. However, for purposes of describing the present embodiment, the display 30 includes an interferometric modulator display, as described herein.

The components of one embodiment of exemplary display device 40 are schematically illustrated in FIG. 6B. The illustrated exemplary display device 40 includes a housing 41 and can include additional components at least partially enclosed therein. For example, in one embodiment, the exemplary display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g. filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 provides power to all components as required by the particular exemplary display device 40 design.

The network interface 27 includes the antenna 43 and the transceiver 47 so that the exemplary display device 40 can communicate with one or more devices over a network. In one embodiment the network interface 27 may also have some processing capabilities to relieve requirements of the processor 21. The antenna 43 is any antenna for transmitting and receiving signals. In one embodiment, the antenna transmits and receives RF signals according to the IEEE 802.11 standard, including IEEE 802.11(a), (b), or (g). In another embodiment, the antenna transmits and receives RF signals according to the BLUETOOTH standard. In the case of a cellular telephone, the antenna is designed to receive CDMA, GSM, AMPS, W-CDMA, or other known signals that are used to communicate within a wireless cell phone network. The transceiver 47 pre-processes the signals received from the antenna 43 so that they may be received by and further manipulated by the processor 21. The transceiver 47 also processes signals received from the processor 21 so that they may be transmitted from the exemplary display device 40 via the antenna 43.

In an alternative embodiment, the transceiver 47 can be replaced by a receiver. In yet another alternative embodiment, network interface 27 can be replaced by an image source, which can store or generate image data to be sent to the processor 21. For example, the image source can be a digital video disc (DVD) or a hard-disc drive that contains image data, or a software module that generates image data.

Processor 21 generally controls the overall operation of the exemplary display device 40. The processor 21 receives data, such as compressed image data from the network interface 27 or an image source, and processes the data into raw image data or into a format that is readily processed into raw image data. The processor 21 then sends the processed data to the driver controller 29 or to frame buffer 28 for storage. Raw data typically refers to the information that identifies the image characteristics at each location within an image. For example, such image characteristics can include color, saturation, and gray-scale level.

In one embodiment, the processor 21 includes a microcontroller, CPU, or logic unit to control operation of the exemplary display device 40. Conditioning hardware 52 generally includes amplifiers and filters for transmitting signals to the speaker 45, and for receiving signals from the microphone 46. Conditioning hardware 52 may be discrete components within the exemplary display device 40, or may be incorporated within the processor 21 or other components.

The driver controller 29 takes the raw image data generated by the processor 21 either directly from the processor 21 or from the frame buffer 28 and reformats the raw image data appropriately for high speed transmission to the array driver 22. Specifically, the driver controller 29 reformats the raw image data into a data flow having a raster-like format, such that it has a time order suitable for scanning across the display array 30. Then the driver controller 29 sends the formatted information to the array driver 22. Although a driver controller 29, such as a LCD controller, is often associated with the system processor 21 as a stand-alone Integrated Circuit (IC), such controllers may be implemented in many ways. They may be embedded in the processor 21 as hardware, embedded in the processor 21 as software, or fully integrated in hardware with the array driver 22.

Typically, the array driver 22 receives the formatted information from the driver controller 29 and reformats the video data into a parallel set of waveforms that are applied many times per second to the hundreds and sometimes thousands of leads coming from the display's x-y matrix of pixels.

In one embodiment, the driver controller 29, array driver 22, and display array 30 are appropriate for any of the types of displays described herein. For example, in one embodiment, driver controller 29 is a conventional display controller or a bi-stable display controller (e.g., an interferometric modulator controller). In another embodiment, array driver 22 is a conventional driver or a bi-stable display driver (e.g., an interferometric modulator display). In one embodiment, a driver controller 29 is integrated with the array driver 22. Such an embodiment is common in highly integrated systems such as cellular phones, watches, and other small area displays. In yet another embodiment, display array 30 is a typical display array or a bi-stable display array (e.g., a display including an array of interferometric modulators).

The input device 48 allows a user to control the operation of the exemplary display device 40. In one embodiment, input device 48 includes a keypad, such as a QWERTY keyboard or a telephone keypad, a button, a switch, a touch-sensitive screen, a pressure- or heat-sensitive membrane. In one embodiment, the microphone 46 is an input device for the exemplary display device 40. When the microphone 46 is used to input data to the device, voice commands may be provided by a user for controlling operations of the exemplary display device 40.

Power supply 50 can include a variety of energy storage devices as are well known in the art. For example, in one embodiment, power supply 50 is a rechargeable battery, such as a nickel-cadmium battery or a lithium ion battery. In another embodiment, power supply 50 is a renewable energy source, a capacitor, or a solar cell, including a plastic solar cell, and solar-cell paint. In another embodiment, power supply 50 is configured to receive power from a wall outlet.

In some implementations control programmability resides, as described above, in a driver controller which can be located in several places in the electronic display system. In some cases control programmability resides in the array driver 22. The above-described optimization may be implemented in any number of hardware and/or software components and in various configurations.

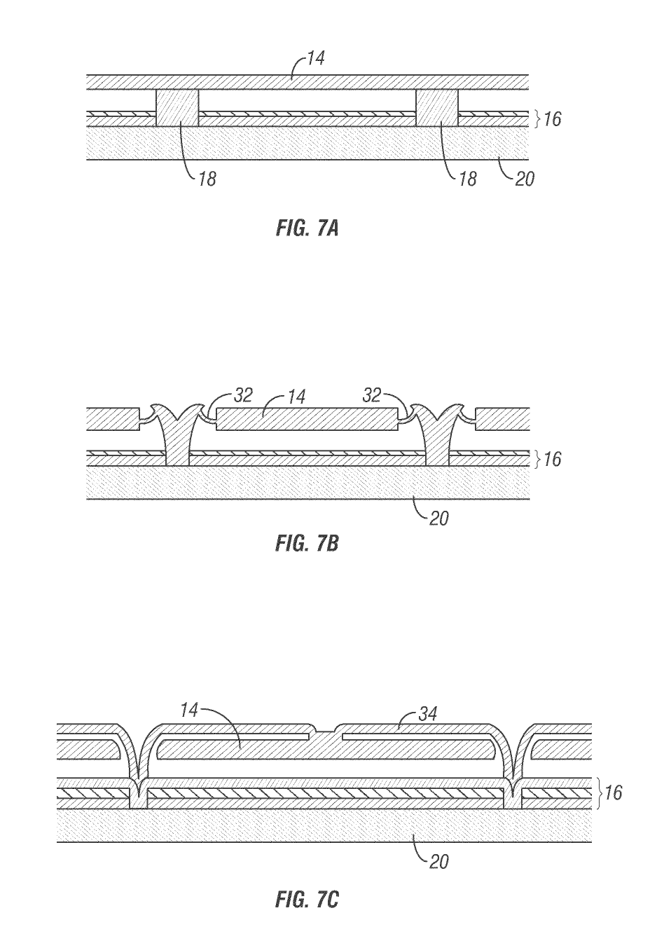

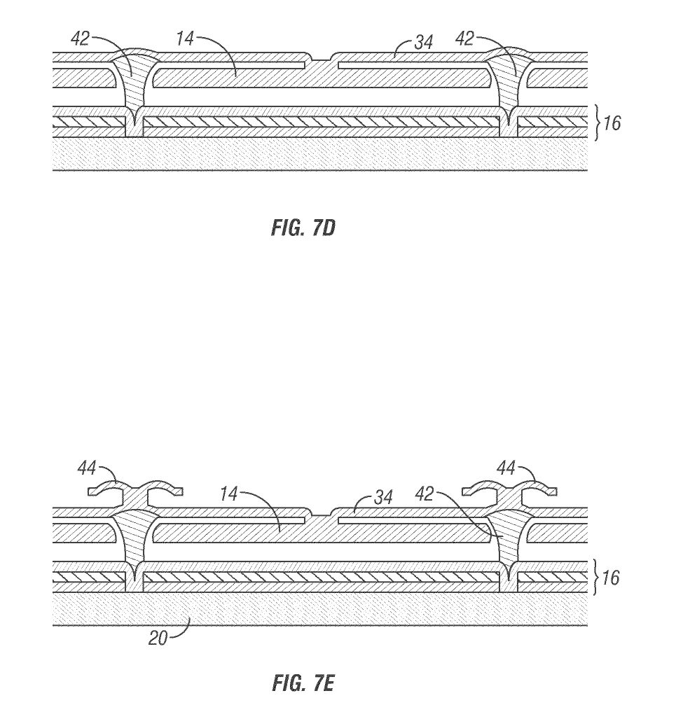

The details of the structure of interferometric modulators that operate in accordance with the principles set forth above may vary widely. For example, FIGS. 7A-7E illustrate five different embodiments of the movable reflective layer 14 and its supporting structures. FIG. 7A is a cross section of the embodiment of FIG. 1, where a strip of metal material 14 is deposited on orthogonally extending supports 18. In FIG. 7B, the moveable reflective layer 14 of each interferometric modulator is square or rectangular in shape and attached to supports at the corners only, on tethers 32. In FIG. 7C, the moveable reflective layer 14 is square or rectangular in shape and suspended from a deformable layer 34, which may comprise a flexible metal. The deformable layer 34 connects, directly or indirectly, to the substrate 20 around the perimeter of the deformable layer 34. These connections are herein referred to as support posts. The embodiment illustrated in FIG. 7D has support post plugs 42 upon which the deformable layer 34 rests. The movable reflective layer 14 remains suspended over the gap, as in FIGS. 7A-7C, but the deformable layer 34 does not form the support posts by filling holes between the deformable layer 34 and the optical stack 16. Rather, the support posts are formed of a planarization material, which is used to form support post plugs 42. The embodiment illustrated in FIG. 7E is based on the embodiment shown in FIG. 7D, but may also be adapted to work with any of the embodiments illustrated in FIGS. 7A-7C as well as additional embodiments not shown. In the embodiment shown in FIG. 7E, an extra layer of metal or other conductive material has been used to form a bus structure 44. This allows signal routing along the back of the interferometric modulators, eliminating a number of electrodes that may otherwise have had to be formed on the substrate 20.

In embodiments such as those shown in FIG. 7A-7E, the interferometric modulators function as direct-view devices, in which images are viewed from the front side of the transparent substrate 20, the side opposite to that upon which the modulator is arranged. In these embodiments, the reflective layer 14 optically shields the portions of the interferometric modulator on the side of the reflective layer opposite the substrate 20, including the deformable layer 34. This allows the shielded areas to be configured and operated upon without negatively affecting the image quality. For example, such shielding allows the bus structure 44 in FIG. 7E, which provides the ability to separate the optical properties of the modulator from the electromechanical properties of the modulator, such as addressing and the movements that result from that addressing. This separable modulator architecture allows the structural design and materials used for the electromechanical aspects and the optical aspects of the modulator to be selected and to function independently of each other. Moreover, the embodiments shown in FIGS. 7C-7E have additional benefits deriving from the decoupling of the optical properties of the reflective layer 14 from its mechanical properties, which are carried out by the deformable layer 34. This allows the structural design and materials used for the reflective layer 14 to be optimized with respect to the optical properties, and the structural design and materials used for the deformable layer 34 to be optimized with respect to desired mechanical properties.

While display devices, including those utilizing interferometric modulators, advantageously employ light to generate display images, in at least certain applications light can be at least partially harmful in addition to its utility. For example, relatively high energy spectra in incident light, such as ultraviolet (UV), can damage or degrade the performance of relatively delicate electrical and/or electromechanical elements of a display. In some embodiments, UV light can excite electrons in the conductive electrode layers and cause charge to build up in the electrodes of the display elements. The added electrical charge can cause a display element to unintentionally actuate to the closed position resulting in defective pixels in the produced image. The UV light can similarly affect the electrical workings of other components of the display if permitted to propagate into the display and reach the components. Thermal heating resulting from incident infrared (IR) can also damage or degrade the performance of display elements. Accordingly, embodiments can include materials, configurations, and/or structures to mitigate damage and/or performance degradation resulting from incident electromagnetic (EM) radiation, including UV and/or IR.

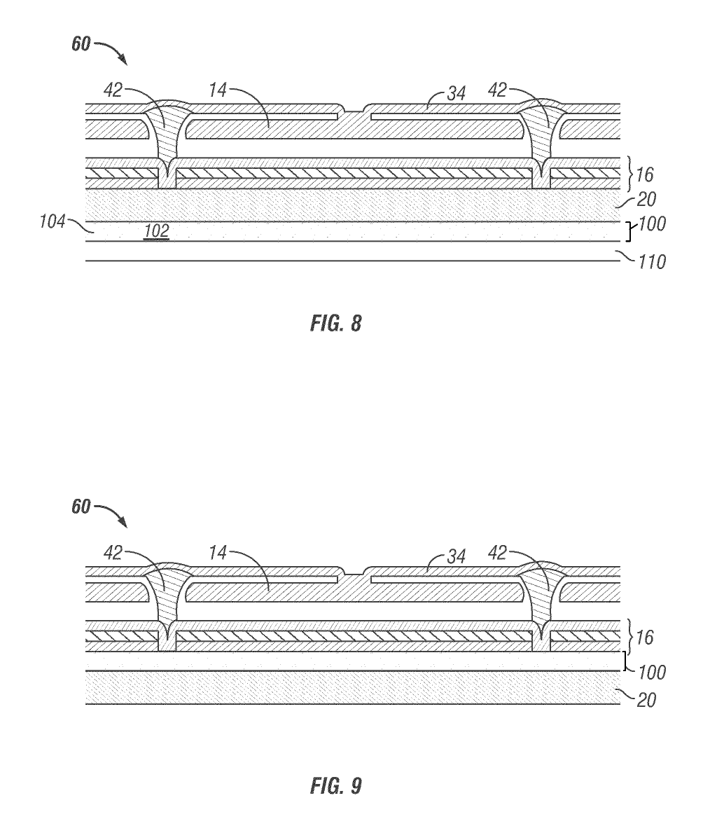

FIG. 8 is a cross section side view of an embodiment of a display element 60 that comprises shielding material 100 which can be for increased protection from incident radiation. The shielding material 100 is formed of material selected that protects the display element 60 against possible deleterious effects of incident EM radiation, such as UV and/or IR. While the embodiments illustrated and described in FIG. 8 and following FIGS. 9-11 will be illustrated and described with respect to a display element 60 comprising an interferometric modulator, this is simply for ease of understanding of implementation and advantages of these embodiments. It will be understood that one of ordinary skill can apply the teachings found herein to other display technologies and other configurations of display element 60 including but not limited to those illustrated and described with respect to FIGS. 7A-7E.

In some embodiments, the shielding material 100 can be selected and arranged to preferentially pass at least certain frequencies/wavelengths of EM radiation, for example wavelengths generally in the visible light range. Embodiments of the shielding material 100 can also be selected and arranged to preferentially block at least certain ranges of wavelengths. As used herein, blocking and shielding refers to one or both of substantially absorbing and reflecting incident radiation in the indicated wavelengths. It will be understood that complete blocking or shielding of a particular wavelength or range of wavelengths is not necessary to achieve the practical advantages provided by various embodiments described and illustrated herein.

In some embodiments, the shielding material 100 is selected to substantially block UV having wavelengths of approximately 350 to 375 nm. In one embodiment, the shielding material 100 is selected to substantially block UV having wavelengths below approximately 350 to 370 nm. In one embodiment, the shielding material 100 is selected to block greater than 95 percent of UV below approximately 350 nm. In one embodiment, the shielding material 100 is selected to block at least 99 percent of UV below approximately 350 nm. In some embodiments, the shielding material 100 is selected to be transmissive by 95 percent or more in the visible light spectrum. In one embodiment, the shielding material 100 is selected to be more than 99 percent transmissive in the visible light spectrum. In some embodiments, the shielding material 100 can be on average at least 95% transmissive for light of wavelengths of approximately 400 nm to approximately 750 nm. For example, in some embodiments, 95% or more of UV light below 350 nm in wavelength incident on the layer of UV shielding material is blocked.

Reference to the blocking and/or transmissive characteristics of the shielding material 100 is to be understood to refer to the bulk properties of the shielding material 100 and for example is not intended to include any surface reflection properties (e.g. Fresnel reflection) of the shielding material 100. For example, in some embodiments, the shielding material 100 can exhibit surface reflection of approximately 4% to approximately 5%. The ranges and values described herein are simply illustrative of certain embodiments and other ranges and values are possible.

In some embodiments, shielding material 100 comprises a matrix 102 (e.g., a glass matrix) and a plurality of EM shielding particles 104 dispersed therein. In some embodiments, the EM shielding particles 104 can be UV shielding particles, although particles for blocking other wavelengths of light are also possible as discussed herein. In some embodiments, UV shielding particles 104 comprise inorganic materials. In some embodiments, the UV shielding particles 104 comprise one or more dielectrics. In various embodiments, the UV shielding particles 104 comprise one or more oxides. In some embodiments, UV shielding particles 104 comprise one or both of titanium dioxide TiO₂ and zinc oxide ZnO. Other materials are possible. In embodiments in which titanium dioxide particles are dispersed in the matrix 102, the material of the matrix can be selected to have an index of refraction such that the shielding material 100 layer is substantially transparent to visible light.

Various materials can be used for the matrix 102. In some embodiments, the matrix 102 is made of an inorganic material (e.g., glass). A suitable inorganic matrix material is a sol-gel coating of molecular precursors of non-UV blocking precursors (silica, alumina, etc.) or mixtures thereof selected such that the matrix refractive index matches some target. Molecular precursors of UV blocking materials (titanium dioxide, zinc oxide, etc.) can be mixed in to provide UV blocking to the inorganic layer. The coating can be applied for example with slot die coating, followed by thermal treatments at high temperatures so that the composite densifies (e.g., about 400° C., with higher temperatures generally leading to further densification). In various embodiments, the resulting coating will contain a generally uniform distribution of UV blocking domains (titanium dioxide, zinc oxide, etc.) with physical dimensions of a few nanometers, and with concentrations set by the initial mixing ratio. Furthermore, using the above described method, the coating can be optically clear (not scattering), and can be formed to a precise desired-thickness.

Another approach is to use a sol-gel precursor of the desired matrix material (an oxide, or a mixture of oxides of silicon, aluminum, zinc, etc.) in which particles of the desired EM blocking material(s) (e.g., titanium dioxide, zinc oxide, etc.) are directly dispersed, rather than using molecular precursors as in the previous example. This can be followed by similar coating and thermal treatment processes as above. This approach allows for the introduction of a wider variety of materials into the structure of the composite than what is allowed by sol-gel chemistry. For example, in some embodiments nanocrystals (e.g., cadmium sulfide CdS, cadmium selenide CdSe, etc.), or other EM blocking particles, can be incorporated into the matrix 102 in addition to, or instead of, the UV blocking particles (titanium dioxide, zinc oxide, etc.).

In some embodiments, shielding material 100 comprising UV shielding particles 104 dispersed in a glass matrix 102 can provide the properties of a diffuser in addition to properties of shielding against selected EM radiation. For example, in one embodiment, UV shielding particles 104 comprising zinc oxide have an index of refraction of approximately 2.0. In certain embodiments, a glass matrix 102 within which the UV shielding particles 104 are dispersed can have an index of refraction of approximately 1.4 to 2.0, and in some embodiments of approximately 1.45 to 1.5. In some embodiments, a higher index matrix 102 material (e.g., an alumina rich mixed oxide such as SiOₓ—Al_{y}O_{z}) can be used for EM blocking particles 104 with a high index of refraction (e.g., titanium dioxide and zinc oxide). The different indices of refraction will have the effect of diffusing or scattering at least certain wavelengths of incident light impinging the shielding material 100. In some embodiments, the UV shielding particles 104 can have a mean size of at least about 0.5 microns and/or no more than about 5 microns. UV shielding particles 104 can be dispersed within a glass matrix 102 at an average concentration or volumetric distribution of at least about 0.5 volume percent and/or no more than about 5 volume percent. In some embodiments, an average concentration or volumetric distribution of at least about 1 volume percent and/or no more than about 3 volume percent can be used. These materials and parameters are simply examples of some embodiments and other materials, sizes, and/or concentrations are possible depending on the needs of particular applications.

In one embodiment, a display element 60 further comprises an outer coating 110. In various embodiments, an outer coating 110 can comprise one or more of an anti-scratch coating, an anti-reflective coating, one or more filter coatings, and the like. In at least some applications, an interface between shielding material 100 comprising zinc oxide and air can give less favorable optical properties. For example, in some embodiments, Fresnel surface reflection can be reduced. In some embodiments, arrangement of the shielding material 100 as an outer layer can negatively affect mechanical properties, such as scratch resistance. In embodiments where one or more organic layers are arranged or applied directly to a material comprising zinc oxide, a potential can exist for chemical degradation of the organic layer(s) at the interface with zinc oxide. Accordingly, in some embodiments, it can be advantageous to passivate the materials, for example by covering or coating the zinc oxide material with transparent inert materials, such as silicon oxide. Thus, in at least some applications, it will be generally preferred to avoid an air/zinc oxide interface. Thus, in certain embodiments, overlaying the outer coating 110 over a shielding material 100 comprising zinc oxide can provide improved optical performance and/or durability characteristics of the display element 60.

In the embodiments illustrated and described with respect to FIG. 8, a substrate 20 is interposed between the shielding material 100 and the optical stack 16 of the display element 60. In some embodiments, the shielding material 100 can be formed directly on the side of the substrate 20 opposite of the optical stack 16 and the display element 60. In the embodiment illustrated in FIG. 9, a shielding material 100 is interposed between the substrate 20 and the optical stack 16. The shielding material 100 can be formed directly on the same side of the substrate 20 as the optical stack 16. The substrate can be used for supporting the display element (e.g., modulators). In particular, in various embodiments, the substrate can also be used to support the display element (e.g., modulator) during fabrication thereof.

In some embodiments, the shielding material 100 can comprise one or more layers of substantially homogeneous material. For example, in some embodiments, the shielding material 100 can comprise a substantially homogeneous layer of zinc oxide configured to be generally transparent in the visible wavelengths. Thicknesses of the shielding material 100 comprising zinc oxide can be selected to provide advantageous properties of blocking UV and transmitting visible light. In some embodiments, the shielding material 100 can comprise a layer of zinc oxide having a thickness of at least about 0.05 microns and/or no more than about 1 micron, although thicknesses outside these ranges can also be used. Additionally, in various embodiments, the shielding material 100 need not be included in a homogeneous layer.

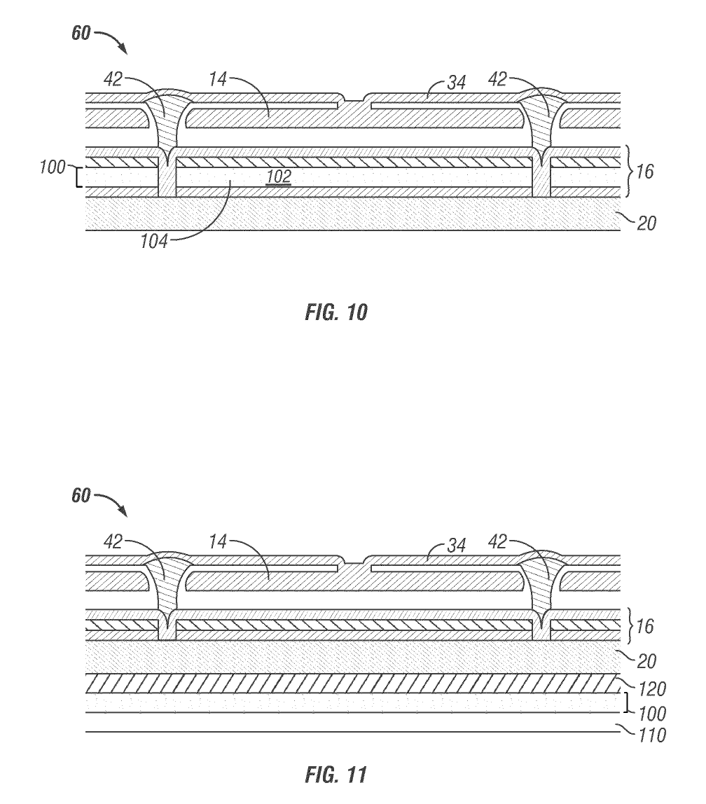

FIG. 10 illustrates a further embodiment of a display element 60 comprising shielding material 100. In the embodiment illustrated in FIG. 10, shielding material 100 is arranged as a layer of the optical stack 16. As previously noted, shielding material 100 can be formed as substantially transparent material. Shielding material 100 can also comprise electrically conductive material. In some embodiments, selected impurities/dopants can be included in the shielding material 100 to achieve desired conductivity properties. Suitable dopants for the shielding material 100 can depend on the particular composition of the shielding material 100 and can include aluminum, niobium, gallium, titanium, and various other suitable materials. Such dopants may be included for example in zinc oxide, such as aluminum doped zinc oxide.

Thus, in at least some embodiments, the shielding material 100 can provide the functionality not only of protecting the display element 60 against deleterious effects of incident EM but can also provide functional utility in the electromechanical operation of a display element 60. For example, in some embodiments, a layer of shielding material 100 can replace and/or supplement a conductive layer such as an indium to oxide (ITO) layer. Such embodiments offer the advantage of a simplified construction by combining multiple functional attributes in a single material/structure. Such embodiments can also offer cost advantages as at least some shielding material 100 components, such as zinc oxide, are less expensive than other materials that can be utilized in an optical stack 16, such as ITO.

In some embodiments, the shielding material 100 can be non-conductive. For example, the shielding material 100 can be formed from EM blocking particles 104 dispersed in a nonconductive matrix. In some embodiments, the EM blocking particles 104 can be conductive (e.g., transparent conductor particles), but the shielding material layer 100 can be nonconductive because of the nonconductive matrix 102. In some embodiments, the EM blocking particles 104 can be nonconductive. The shielding material 100 can also be formed from a substantially homogeneous nonconductive film or layer. For example, in some embodiments, a film of undoped zinc oxide can be used to block UV light. A nonconductive shielding material 100 can, in some embodiments, advantageously block UV light with reduced building up of charge in the shielding material 100 or in other portions of the display device.

FIG. 11 illustrates an additional embodiment of a display element 60 with shielding material 100. In this embodiment, the substrate 20 is again interposed between the optical stack 16 and the shielding material 100. The outer coating 110 is also formed at a more outward position with respect to the shielding material 100 (e.g., more forward and closer to the viewer). In this embodiment, the display element 60 further comprises a lighting assembly 120. The lighting assembly 120 is configured to inject light towards the display element 60 to facilitate utilization of the optical display properties thereof. The light assembly 120 can include one or more light sources, a light guide, one or more light turning features (e.g., on or in the light guide), one or more diffuser/filter features, and the like. Such features of embodiments of the light assembly 120 are not illustrated for ease of understanding, however will be readily understood by one of ordinary skill. In some embodiments, the light assembly 120 can be considered as being arranged toward the “front” (e.g. forward) of the display element 60 and the light assembly 120 can be considered a front light assembly 120. Other arrangements and configurations of the light assembly 120 are possible.

A wide variety of methods may be employed to form the display element 60 and shielding layer 100. For example, shielding material 100 comprising inorganic materials can, in certain embodiments, be applied via sputtering or other deposition techniques which are already employed in processes for forming display elements 60. In some embodiments, the shielding material 100 includes substantially no organic materials. In some embodiments, the inorganic materials used for the shielding material 100 can withstand the high temperatures or other conditions present during the deposition process used to form the display elements 60. By applying the shielding material 100 as part of the same deposition process that is used to form the display elements 60, the cost and complexity of incorporating the shielding material 100 into the display can be reduced. In some embodiments, the use of inorganic materials for the shielding material 100 can allow the shielding material to be formed on the process side of the substrate along with the display elements 60. In some embodiments, the inorganic materials can be compatible with the fabrication process used to form the display elements on the substrate. For example, in some embodiments, the inorganic material will not deteriorate under the process of fabrication (e.g., under high temperature), and will not contaminate or degrade or interfere with the other processing steps or the processing equipment.

Thus, embodiments provide significant advantages to the use, fabrication, and performance of the display element 60. Embodiments of the shielding material 100 comprising inorganic materials, such as oxide materials, are generally more compatible with existing fabrication processes than alternative UV shielding materials, such as organic materials. Embodiments provide shielding material 100 that can significantly reduce deleterious effects to the display elements 60 and other materials such as plastics or other polymers that can be combined with the display elements 60 into larger integrations. For example, embodiments can provide protection against performance degradation of the electrical and/or mechanical operation of elements of a display. For example, in some embodiments, the shielding material 100 can be disposed forward (closer to the viewer) than the electrodes of the display element 60, to block high energy UV light from reaching the electrodes. By blocking the UV light, the build up of UV light induced charge in the electrodes can be reduced to avoid unintentional actuation of the display elements. Some embodiments can provide protection against thermal heating that could otherwise accelerate degradation of materials comprising display elements 60.

Additional valuable characteristics of the shielding material 100 can include the ability to reduce deleterious effects of multiple wavelength ranges of incident EM. For example, in some embodiments the shielding material 100 is formed not only to substantially block UV and pass visible light but also to substantially attenuate or block (e.g., reflect) a substantial portion of incident IR. Various suitable IR blocking materials can be used. For example, in some embodiments, the matrix 102 can include IR reflecting particles 104. In some embodiments, the IR reflecting particles 104 can be selected from the class of particles known as transparent conductors, such as zinc oxide or indium tin oxide or other oxides doped with aluminum or with other suitable dopants. The transparent conductor particles can act effectively as metal mirrors to light in the IR spectrum. In various embodiments, when the transparent conductor particles 104 are suspended in the matrix 102, the particles 104 can be separated by the matrix material such that the shielding material layer 100 is nonconductive. In some embodiments, the shielding material 100 can scatter IR light. In some embodiments, the shielding material 100 can be a substantially homogeneous layer of the transparent conductor material such that the shielding material 100 reflects high amounts of IR light. In some embodiments, the shielding material 100 can block at least an average of approximately 30%, 40%, 50%, 60%, 70%, 80%, 90%, 95%, 99% or more of IR light having a wavelength of at least about 3 microns, at least about 5 microns, at least about 7 microns, at least about 9 microns, and/or up to about 10 to 20 microns, although IR light outside these ranges can also be blocked (e.g., reflected) by the shielding material 100. Incident IR can induce thermal heating of the display element 60 and in at least some implementations, compensating systems/structures would be needed to compensate for the thermal heating effects and the resulting changes in the electromechanical operation of the display element 60. Provision of the shielding material 100 configured to block IR light may reduce the complexity and expense of providing such mitigation systems/structures.

The composition and dimensions of the shielding material 100 can also be adjusted to provide variable optical effects to achieve desired performance of selected display elements 60 in an array of the display elements 60. For example, the composition, thickness, and the like of shielding material arranged adjacent a selected display element 60 can be adjusted, for example, to preferentially absorb blue light to adjust the optical characteristics of the associated display element 60. In some implementations, individual display elements 60 in an array of the display elements 60 are configured to provide the optical appearance of a selected color and the shielding material 100 can be adjusted to improve the display performance of respective display elements 60.

As discussed above, in some embodiments the dark state of the display element 60 can reflect visible light near the UV spectrum. This far-blue light can cause the dark state of the display element 60 to have a deep blue color. In some embodiments, the shielding material 100 can include an optical absorbing material for absorbing visible light near the UV spectrum. The far-blue light that would normally be reflected by the display element 60 even when in the dark state can be reduced, thereby darkening the dark state and increasing the contrast ratio of the display element 60. In some embodiments, the shielding material 100 can be configured to block (e.g., absorb) an average of at least about 50%, at least about 75%, at least about 90%, at least about 95%, or at least about 99% of visible light below the wavelength of about 400 nm, or below about 420 nm, or below 450 nm.

Various suitable materials can be used to absorb the far-blue light such as semiconductor nanocrystals (quantum dots). Suitable nanocrystals for absorbing blue light include cadmium selenide CdSe and cadmium sulfide CdS. In some embodiments, the far-blue light absorbing particles 100 can be suspended in a matrix 102 (e.g., glass) as described above. By adjusting the size of the particles, or by changing the matrix in which the particles are suspended, the absorptive properties of the shielding layer 100 can be adjusted according to the requirements of the particular application. For example, in some cases, increasing the size of the semiconductor nanocrystals can result in a wider range of wavelengths that are absorbed by the shielding material 100. In some embodiments, the nanocrystals can have diameters chosen small enough to reduce the optical absorption in the visible spectrum, other than the targeted far-blue light. For example, in some embodiments, the nanocrystals can be configured to not substantially absorb visible light above the wavelength of about 450 nm, or about 420 nm, or about 400 nm. In some embodiments, zinc oxide and/or other types of absorbing particles can be combined in a matrix to provide a layer with the desired optical absorption properties. Accordingly, in some embodiments UV and/or IR blocking material and material that absorbs blue can be combined in a layer. Laser dyes can also be used as absorbers. In some embodiments, the shield material 100 can comprise multiple layers, which can combine to provide the desired optical absorption properties. For example, in some embodiments, one layer can provide a first absorption (e.g. UV light) and another layer (blue light) can provide a second absorption and the combination can provide an aggregate absorption.

In various embodiments, the blue absorbing material is also inorganic such that the absorbing material is not affected by high temperature processing steps used to fabricate the display element (e.g., interferometric modulator). Similarly, in various embodiments the shielding layer comprises substantially only material that is not affected by high temperature processing steps used to fabricate the display element (e.g., interferometric modulator). In some embodiments, for example, the shielding layer is made of entirely or almost entirely material (e.g., inorganic) that can withstand the higher processing temperature. In some embodiments, for example, the shielding layer comprises at least 95%, 96%, 97%, 98%, 99%, 99.5%, 99.9% or more of such material. For example, in some embodiments the matrix material in which UV and/or IR blocking particles and blue filter material is included is inorganic or is otherwise able to be exposed to the processing steps used to fabricate the modulator.

Although the above disclosed embodiments of the present teachings have shown, described and pointed out the fundamental novel features of the invention as applied to the above-disclosed embodiments, it should be understood that various omissions, substitutions, and changes in the form of the detail of the devices, systems and/or methods illustrated may be made by those skilled in the art without departing from the scope of the present teachings. Components, devices, and features and may be added, removed, or rearranged in different embodiments. Similarly processing steps be added, removed, or reordered in different embodiments. Accordingly, the scope of the invention should not be limited to the foregoing description but should be defined by the appended claims.

What is claimed is:

1. A display device comprising:
a substrate;
a plurality of display elements arranged on a first side of the substrate; and
a nonconductive UV shielding layer comprising substantially no organic material, the UV shielding layer disposed forward of the plurality of display elements such that visible light passes through the UV shielding layer to the plurality of display elements and such that the UV shielding layer blocks 95% or more of UV light below 350 nm in wavelength that is incident on the UV shielding layer from reaching the plurality of display elements.

2. The display device of claim 1, wherein the UV shielding layer comprises an oxide.

3. The display device of claim 2, wherein the UV shielding layer comprises zinc oxide.

4. The display device of claim 1, wherein the UV shielding layer comprises only inorganic material.

5. The display device of claim 1, wherein the plurality of display elements comprise MEMS devices.

6. The display device of claim 1, wherein the plurality of display elements comprise interferometric modulators.

7. The display device of claim 1, wherein the UV shielding layer is disposed between the substrate and the plurality of display elements.

8. The display device of claim 7, wherein the UV shielding layer is formed on the first side of the substrate.

9. The display device of claim 1, wherein the substrate is disposed between the UV shielding layer and the plurality of display elements.

10. The display device of claim 9, wherein the UV shielding layer is formed on a second side of the substrate that is opposite the first side.

11. The display device of claim 9, further comprising an outer coating overlying the UV shielding layer, wherein the outer coating comprises at least one of an anti-reflective coating, an anti-scratch coating, and a filter coating.

12. The display device of claim 1, wherein the UV shielding layer comprises a plurality of UV shielding particles dispersed in a matrix material.

13. The display device of claim 12, wherein the matrix material is glass.

14. The display device of claim 12, wherein the UV shielding layer comprises molecular precursors for the UV shielding particles.

15. The display device of claim 12, wherein the UV shielding layer comprises a heterogeneous layer of inorganic materials.

16. The display device of claim 12, wherein the UV shielding particles are configured to reflect IR light.

17. The display device of claim 16, wherein the UV shielding particles are transparent conductor particles.

18. The display device of claim 12, wherein the UV shielding layer further comprises inorganic blue absorbing particles configured to absorb visible light near the UV spectrum dispersed in the matrix material.

19. The display device of claim 16, wherein the UV shielding layer further comprises inorganic blue absorbing particles configured to absorb visible light near the UV spectrum dispersed in the matrix material.

20. The display device of claim 18, wherein the blue absorbing particles comprise semiconductor nanocrystals.

21. The display device of claim 1, wherein the UV shielding layer comprises a substantially homogenous layer of inorganic material.

22. The display device of claim 1, wherein the UV shielding layer blocks 99% or more of UV light below 350 nm in wavelength that is incident on the UV shielding layer.

23. The display device of claim 1, wherein the UV shielding layer absorbs no more than 1% of visible light that is incident on the UV shielding layer.

24. The display device of claim 1, wherein at least one of the plurality of display elements comprises an optical stack and wherein the optical stack comprises the UV shielding layer.

25. The display device of claim 1, further comprising:
a processor that is configured to communicate with said display device, said processor being configured to process image data; and
a memory device that is configured to communicate with said processor.

26. The display device of claim 25, further comprising a driver circuit configured to send at least one signal from the processor to said display device.

27. The display device of claim 26, further comprising a controller configured to send at least a portion of said image data to said driver circuit.

28. The display device of claim 25, further comprising an image source module configured to send said image data to said processor.

29. The display device of claim 28, wherein said image source module comprises at least one of a receiver, transceiver, and transmitter.

30. The display device of claim 25, further comprising an input device configured to receive input data and to communicate said input data to said processor.

31. The display device of claim 1, further comprising a light assembly arranged to direct light towards the plurality of display elements.

32. The display device of claim 31, wherein the light assembly comprises a light guide.

33. The display device of claim 1, wherein the UV shielding layer comprises titanium dioxide particles suspended in a matrix, wherein the matrix is selected to have an index of refraction such that the UV shielding layer transmits 95% or more of visible light.

34. The display device of claim 1, wherein at least one of the plurality of display elements comprises one or more electrodes for facilitating the actuation of the at least one display element, and wherein the UV shielding layer is disposed forward of the one or more electrodes such that the UV shielding layer blocks 95% or more of UV light below 350 nm in wavelength that is incident on the UV shielding layer from reaching the one or more electrodes.

35. A method of manufacturing a display device, the method comprising:
providing a substrate;
arranging a plurality of display elements on a first side of the substrate; and
disposing a nonconductive UV shielding layer comprising substantially no organic material forward of the plurality of display elements such that visible light passes through the UV shielding layer to the plurality of display elements and such that 95% or more of UV light below 350 nm in wavelength that is incident on the UV shielding layer is blocked from reaching the plurality of display elements.

36. A display device, comprising:
means for supporting;
means for displaying an image arranged on a first side of the supporting means; and
means for UV shielding disposed forward of the displaying means such that visible light passes through the UV shielding means to the displaying means, and such that the UV shielding means blocks 95% or more of UV light that is incident on the UV shielding means from reaching the displaying means, and wherein the UV shielding means comprises substantially only inorganic material.

37. The display device of claim 36, wherein the supporting means comprises a transparent substrate, or the displaying means comprises a plurality of display elements, or the UV shielding means comprises a UV shielding layer.

38. A display device comprising:
at least one display element having a dark state and a light state, wherein the at least one display element emits visible light near the UV spectrum when in the dark state; and
an optical shielding layer disposed forward of the at least one display element such that visible light passes through the optical shielding layer to the at least one display element and such that the optical shielding layer blocks UV light that is incident on the optical shielding layer from reaching the at least one display element, and wherein the optical shielding layer blocks visible light near the UV spectrum so as to darken the dark state of the at least one display element.

39. The display device of claim 38, wherein the optical shielding layer absorbs an average of at least about 50% of visible light below 400 nm in wavelength that is incident on the UV shielding layer.

40. The display device of claim 38, wherein the optical shielding layer comprises substantially only inorganic material.

41. The display device of claim 40, wherein the optical shielding layer comprises zinc oxide.

42. The display device of claim 38, wherein the optical shielding layer comprises multiple layers, wherein a first layer is configured to block the UV light and a second layer is configured to block the visible light near the UV spectrum.

43. The display device of claim 38, wherein the optical shielding layer comprises a single layer configured to block both the UV light and the visible light near the UV spectrum.
